(19) United States
(12) Patent Application Publication
(10) Pub. No.: US 2008/0224139 A1
(43) Pub. Date: Sep. 18, 2008

(54) THIN FILM TRANSISTOR

(75) Inventors: Chin-Chuan Lai, Taoyuan County (TW); Chuan-Yi Wu, Taipei City (TW); Yi-Yun Tsai, Penghu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 11/775,874

(22) Filed: Jul. 11, 2007

(30) Foreign Application Priority Data
Mar. 14, 2007 (TW) 96108695

(51) Int. Cl. H01L 29/06

(52) U.S. Cl. 257/57; 257/E29.003

(57) ABSTRACT

A thin film transistor including a substrate, a gate, a gate insulator layer, a semiconductor layer, an ohmic contact layer, a source and a drain is provided. The gate is disposed on the substrate while the gate insulator layer is disposed on the substrate and covers the gate. The semiconductor layer is disposed on the gate insulator layer above the gate. The semiconductor layer includes an undoped amorphous silicon layer and a first undoped microcrystalline silicon (μc-Si) layer, wherein the first undoped μc-Si layer is disposed on the undoped amorphous silicon layer. The ohmic contact layer is disposed on part of the semiconductor layer and the source and the drain are disposed on the ohmic contact layer. Therefore, the thin film transistor has better quality control and electrical characteristics.

### CROSS-REFERENCE TO RELATED APPLICATION

This application claims the priority benefit of Taiwan application serial no. 96108695, filed Mar. 14, 2007. All disclosure of the Taiwan application is incorporated herein by reference.

### BACKGROUND OF THE INVENTION

1. Field of the Invention

The present invention generally relates to a semiconductor device, and more particular to a thin film transistor (TFT).

2. Description of Related Art

In recent years, the maturity of optical-electrical techniques and semiconductor fabrication techniques leads to the rapid development of flat panel display. In the thin film transistor liquid crystal display (TFT-LCD), thin film transistors are used to control the liquid crystal layer. The advantages of TFT-LCD include low operating voltage, rapid response, light weight and small volume. With these advantages, TFT-LCD has become the mainstream display product.

FIG. 1 is a schematic cross-sectional view of a conventional thin film transistor. As shown in FIG. 1, the conventional thin film transistor 100 includes a substrate 110, a gate 120, a gate insulator layer 130, a semiconductor layer 140, an ohmic contact layer 150, a source 160 and a drain 170. The gate 120 is disposed on the substrate 110 while the gate insulator layer 130 is disposed on the substrate 110 and covers the gate 120. The ohmic contact layer 150 is disposed on part of the semiconductor layer 140 and the source 160 and the drain 170 are disposed on the ohmic contact layer 150. When a voltage is applied to the gate 120, the semiconductor layer 140 has conductive characteristics so that the source 160 and the drain 170 are electrically connected. More precisely, the semiconductor layer 140 can be regarded as a critical layer that controls the operation of a conventional thin film transistor 100.

However, in the conventional thin film transistor 100, the material of the semiconductor layer 140 and the ohmic contact layer 150 are undoped amorphous silicon and doped amorphous silicon respectively. In general, the etching selectivity ratio between undoped amorphous silicon and doped amorphous silicon is quite small. Therefore, when performing the back channel etching process, part of the area of the semiconductor layer 140 may be etched to produce a recess 180 (as shown in FIG. 1) or form an uneven surface. Moreover, part of the ohmic contact layer 150 that needs to be removed may be incompletely etched. As a result, the percentage of defective thin film transistor 100 will be significantly increased.

To increase the process yield of the thin film transistor 100, thickness of the semiconductor layer 140 can be increased to avoid the aforementioned problem. However, the semiconductor layer 140 has electron and hole conduction capacity only within 40 nm of the contact surface with the gate insulator layer 130. Therefore, thickening the semiconductor layer 160 will lead to poorer electrical performance of the thin film transistor 100. Consequently, there is a need to improve the fabrication process of the conventional thin film transistor 100.

### SUMMARY OF THE INVENTION

Accordingly, the present invention is directed to a thin film transistor for increasing the process yield thereof.

According to an embodiment of the present invention, a thin film transistor is provided. The thin film transistor includes a substrate, a gate, a gate insulator layer, a semiconductor layer, an ohmic contact layer, a source and a drain. The gate is disposed on the substrate while the gate insulator layer is disposed on the substrate and covers the gate. The semiconductor layer is disposed on the gate insulator layer above the gate. The semiconductor layer includes an undoped amorphous silicon layer and a first undoped microcrystalline silicon (μc-Si) layer, wherein the first undoped μc-Si layer is disposed on the undoped amorphous silicon layer. The ohmic contact layer is disposed on part of the semiconductor layer and the source and the drain are disposed on the ohmic contact layer.

In an embodiment of the present invention, the thickness of the first undoped μc-Si layer is between 20 nm-90 nm, for example. Preferably, the thickness of the first undoped μc-Si layer is between 30 nm-80 nm, and more preferably, the thickness of the first undoped μc-Si layer is between 40 nm-70 nm.

In an embodiment of the present invention, the thin film transistor further includes a second undoped μc-Si layer disposed between the undoped amorphous silicon layer and the gate insulator layer. The thickness of the second undoped μc-Si layer is between 5 nm-70 nm, for example. Preferably, the thickness of the second undoped μc-Si layer is between 5 nm-50 nm, and more preferably, the thickness of the second undoped μc-Si layer is between 10 nm-40 nm.

In an embodiment of the present invention, the material of the ohmic contact layer is doped amorphous silicon or doped μc-Si, for example.

In the present invention, a first undoped μc-Si layer is formed on the undoped amorphous silicon layer so as to protect the undoped amorphous silicon layer against damage due to the etching process. Hence, the process yield of the thin film transistor is increased. Besides, a second undoped μc-Si layer may be formed between the undoped amorphous silicon layer and the gate insulator layer to further improve the electrical performance of the thin film transistor.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional thin film transistor.

FIG. 2A is a schematic cross-sectional view of a thin film transistor according to an embodiment of the present invention.

FIG. 2B is a schematic cross-sectional view of a thin film transistor according to another embodiment of the present invention.

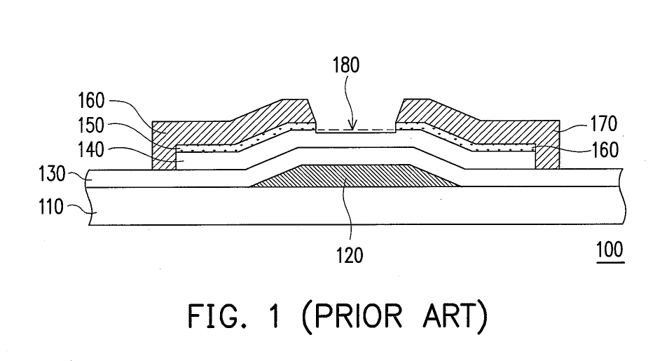

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

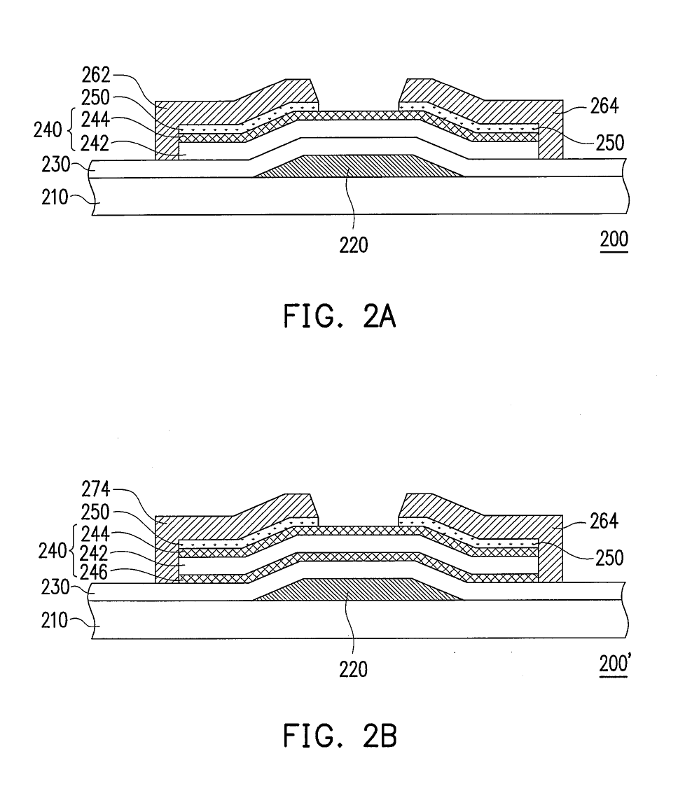

FIG. 2A is a schematic cross-sectional view of a thin film transistor according to an embodiment of the present invention. As shown in FIG. 2A, the thin film transistor 200 includes a substrate 210, a gate 220, a gate insulator layer 230, a semiconductor layer 240, an ohmic contact layer 250, a source 262 and a drain 264. The gate 220 and the gate insulator layer 230 are disposed on the substrate 210 and the gate insulator layer 230 covers the gate 220. The semiconductor layer 240 is disposed on the gate insulator layer 230 and is located above the gate 220. The semiconductor layer 240 includes an undoped amorphous silicon layer 242 and a first undoped microcrystalline silicon (μc-Si) layer 244, wherein the first undoped μc-Si layer 244 is disposed on the undoped amorphous silicon layer 242. The ohmic contact layer 250 is disposed on part of the first undoped μc-Si layer 244 of the semiconductor layer 240. The source 262 and the drain 264 are disposed on the ohmic contact layer 250. In the present embodiment, the material of the ohmic contact layer 250 is doped amorphous silicon or doped μc-Si, for example.

In the present embodiment, the thickness of the first undoped μc-Si layer 244 is between 20 nm-90 nm, for example. Preferably, the thickness of the first undoped μc-Si layer is between 30 nm-80 nm, and more preferably, the thickness of the first undoped μc-Si layer is between 40 nm-70 nm.

In the present embodiment, the first undoped μc-Si layer 244 is disposed on the undoped amorphous silicon layer 242. Because of the advantages of small defect density, structural compactness and high etching resistance of the first undoped μc-Si layer 244, the first undoped μc-Si layer 244 can protect the undoped amorphous silicon layer 242 against damages caused by a back channel etching (BCE) operation. As a result, the desired electrical characteristics of the thin film transistor are preserved. In other words, the first undoped μc-Si layer 244 can increase the process yield of the thin film transistor 200.

The method of forming the first undoped μc-Si layer 244 is, for example, growing a microcrystalline silicon (μc-Si) film with H₂:SiH₄ set to a ratio greater than 20:1.

In addition, the undoped amorphous silicon layer 242 formed using amorphous silicon material has the demerits of a relatively irregular atomic arrangement and a relatively high defect density. Therefore, when the undoped amorphous silicon layer 242 formed using amorphous silicon material is used to fabricate the thin film transistor 200, dangling bonds are easily formed in the undoped amorphous silicon layer 242 to affect the electrical characteristics of the thin film transistor 200. Therefore, the present invention also provides a thin film transistor 200′ having a sandwiched structure to improve the electrical characteristics.

FIG. 2B is a schematic cross-sectional view of a thin film transistor according to another embodiment of the present invention. As shown in FIG. 2B, the thin film transistor 200′ in the present embodiment is similar to the foregoing thin film transistor 200. The main difference is that the thin film transistor 200′ in the present embodiment further includes a second undoped μc-Si layer 246 disposed between the undoped amorphous silicon layer 242 and the gate insulator layer 230. Furthermore, the method of forming the second undoped μc-Si layer 246 is similar to the foregoing method of forming the first undoped μc-Si layer 244.

In the present embodiment, the thickness of the second undoped μc-Si layer 246 is between 5 nm-70 nm, for example. Preferably, the thickness of the second undoped μc-Si layer 246 is between 5 nm-50 nm, and more preferably, the thickness of the second undoped μc-Si layer 246 is between 10 nm-40 nm.

Because the second undoped μc-Si layer 246 has a more compact structure, the electron or hole mobility of the thin film transistor 200′ is increased. Moreover, the first undoped μc-Si layer 244 and the second undoped μc-Si layer 246 have fewer defects. Therefore, the thin film transistor 200′ has a lower off-current. In other words, the thin film transistor 200′ has better electrical characteristics.

In summary, the thin film transistor of the present invention has at least the following advantages:

1. The first undoped μc-Si layer can protect the undoped amorphous silicon layer against etching in the back channel etching process and increase the uniformity of the etching process.

2. The first and second undoped μc-Si layers can reduce ‘off’ current and improve electrical characteristics. In other words, the thin film transistor of the present invention has improved electrical characteristics and higher processing yield.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a substrate;
a gate, disposed on the substrate;
a gate insulator layer, disposed on the substrate and covering the gate;
a semiconductor layer, disposed on the gate insulator layer and located above the gate, the semiconductor comprising:
an undoped amorphous silicon layer; and
a first undoped microcrystalline silicon (μc-Si) layer, disposed on the undoped amorphous silicon layer;
an ohmic contact layer, disposed on part of the semiconductor layer; and
a source and a drain, disposed on the ohmic contact layer.

2. The thin film transistor according to claim 1, wherein the first undoped μc-Si layer has a thickness between 20 nm-90 nm.

3. The thin film transistor according to claim 2, wherein the first undoped μc-Si layer has a thickness between 30 nm-80 nm.

4. The thin film transistor according to claim 3, wherein the first undoped μc-Si layer has a thickness between 40 nm-70 nm.

5. The thin film transistor according to claim 1, wherein the semiconductor layer further comprises a second undoped μc-Si layer disposed between the undoped amorphous silicon layer and the gate insulator layer.

6. The thin film transistor according to claim 5, wherein the second undoped μc-Si layer has a thickness between 5 nm-70 nm.

7. The thin film transistor according to claim 6, wherein the second undoped μc-Si layer has a thickness between 5 nm-50 nm.

8. The thin film transistor according to claim 6, wherein the second undoped μc-Si layer has a thickness between 10 nm-40 nm.

9. The thin film transistor according to claim 1, wherein material of the ohmic contact layer comprises undoped amorphous silicon or doped microcrystalline silicon.
